(19) United States
(12) Patent Application Publication
(10) Pub. No.: US 2006/0181858 A1
(43) Pub. Date: Aug. 17, 2006

(54) Heat dissipation device and heat dissipation method for electronic equipment

(75) Inventor: Kazuhiro Kamemoto, Fukaya-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/349,255

(22) Filed: Feb. 8, 2006

(30) Foreign Application Priority Data
Feb. 14, 2005 (JP) 2005-036595

(51) Int. Cl. H05K 7/20

(52) U.S. Cl. 361/719

(57) ABSTRACT

According to one embodiment, a heat conduction sheet is attached to a circuit component mounted on a circuit board, and a heat sink is caused to come into contact with the heat conduction sheet. When a shield case covers the surface of the circuit board including the circuit component, presser portions formed to the shield case press the heat sink such that it is caused to come into intimate contact with the heat conduction sheet at predetermined pressure.

### CROSS-REFERENCE TO RELATED APPLICATIONS

This application is based upon and claims the benefit of priority from Japanese Patent Application No. 2005-036595, filed Feb. 14, 2005, the entire contents of which are incorporated herein by reference.

### BACKGROUND

1. Field

One embodiment of the invention relates to electronic equipment, for example, a digital television broadcasting receiver and the like, and a more particularly, to a heat dissipation device and a heat dissipation method for dissipating heat from heat generating circuit components.

2. Description of the Related Art

As known well, in recent years, digitalization of television broadcasting is promoted. For example, in Japan, terrestrial digital broadcasting starts in addition to satellite digital broadcasting such as BS (broadcasting satellite) digital broadcasting, 110° CS (communication satellite) digital broadcasting, and the like.

In digital broadcasting receivers for receiving such digital television broadcasting, since it is required to process, in particular, digital video data at high speed, a circuit component such as an LSI (large scale integration) and the like that execute the high speed processing generates heat. Thus, it is vital to employ a countermeasure for dissipated heat.

Jpn. Pat. Appln. KOKAI Publication No. 9-64582 discloses an arrangement that a hole is formed in a flat surface of a shield case that is parallel to the surface of a circuit board, and a metal distinct piece is attached to the peripheral edge portion of the hole so as to come into contact with a heat generating component mounted on the circuit board. In this case, the metal distinct piece is attached to the shield case in such a manner that the peripheral edge portion of the hole is clamped in the direction of thickness by a pair of projections projecting from the metal distinct piece in parallel to the flat surface of the shield case.

U.S. Pat. No. 5,060,114 discloses an arrangement that a heat generating component is caused to come into contact with a heat sink acting also as a shield case through a flexible gel-like pad. In this case, the heat sink is caused to come into pressure contact with the heat generating component by the elastic force generated by the heat sink itself. Jpn. Pat. Appln. KOKAI Publication No. 2002-359330 and U.S. Pat. No. 5,384,940 disclose an arrangement that a heat dissipating member is caused to come into pressure contact with a heat generating component by a leaf spring or a Coil spring.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block constitutional view that shows an embodiment of the present invention and explains a video signal processing system of a television broadcasting receiver;

FIG. 2 is an exploded perspective view explaining a circuit board on which the video signal processing system of the embodiment is arranged;

FIGS. 3 and 4 are side sectional views explaining an attachment structure of a heat sink and a shield case of the embodiment, respectively;

FIG. 5 is a graph explaining an example of the load vs compression ratio characteristic of flexible silicon used as a material of a heat conduction sheet in the embodiment;

FIG. 6 is an exploded perspective view explaining a modification of the shield case in the embodiment;

FIG. 7 is an exploded perspective view showing another modification of the shield case in the embodiment;

FIG. 8 is an exploded perspective view explaining a modification of the heat sink in the embodiment;

FIG. 9 is a side sectional view showing another embodiment of the present invention and explaining an attachment structure of the heat sink and the shield case; and

FIG. 10 is a side sectional view showing still another embodiment of the present invention and explaining an attachment structure of the heat sink and the shield case.

### DETAILED DESCRIPTION

Various embodiments according to the invention will be described hereinafter with reference to the accompanying drawings. In general, according to one embodiment of the invention, a heat conduction sheet is attached to a circuit component mounted on a circuit board, and a heat sink is caused to come into contact with the heat conduction sheet. When a shield case covers the surface of the circuit board including the circuit component, presser portions formed to the shield case press the heat sink such that it is caused to come into intimate contact with the heat conduction sheet at predetermined pressure.

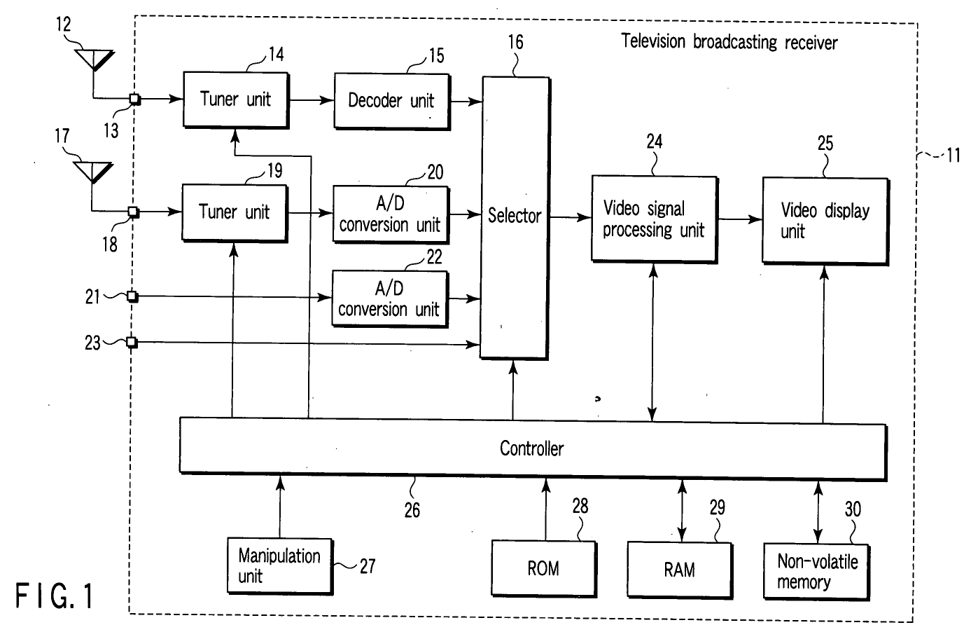

An embodiment of the present invention will be explained below in detail with reference to the drawings. FIG. 1 schematically shows a video signal processing system of a television broadcasting receiver 11 explained in the embodiment. More specifically, a digital television broadcasting signal received by an antenna 12 for receiving digital television broadcasting is supplied to a tuner unit 14 through an input terminal 13.

The tuner unit 14 selects and demodulates the signal of a desired channel from the digital television broadcasting signal input thereto. The signal output from the tuner unit 14 is supplied to a decoder unit 15, subjected to, for example, MPEG (moving picture experts group) 2 decode processing therein, and then supplied to a selector 16.

Further, an analog television broadcasting signal received by an antenna 17 for receiving analog television broadcasting is supplied to a tuner unit 19 through an input terminal 18. The tuner 19 selects and demodulates the signal of a desired channel from the analog television broadcasting signal input thereto. The signal output from the tuner unit 19 is output to the selector 16 after it is digitized by an A/D (analog/digital) conversion unit 20.

Further, an analog video signal supplied to an external input terminal 21 for analog video signal is output to the selector 16 after it is supplied to an A/D conversion unit 22 to be digitized. Further, a digital video signal supplied to an external input terminal 23 for digital video signal is supplied to the selector 16 as it is.

The selector 16 selects one of the four types of digital video signals input thereto and supplies it to a video signal processing unit 24. The video signal processing unit 24 subjects the digital video signal input thereto to predetermined signal processing so that it is displayed on a video display unit 25. Employed as the video display unit 25 is a flat panel display composed of, for example, a liquid crystal display, a plasma display, and the like.

In the television broadcasting receiver 11, various types of operations including the various types of the signal receiving operations described above are integrally controlled by a controller 26. The controller 26 is composing a microprocessor including a CPU (central processing unit) and controls the respective units in response to manipulation information from a manipulation unit 27 including a remote controller (not shown) and the like so that the manipulation contents of the manipulation information are reflected.

In this case, the controller 26 mainly makes use of a ROM (read only memory) 28 in which a control program to be executed by the CPU is stored, a RAM (random access memory) 29 for providing the CPU with a working area, and a non-volatile memory 30 in which various types of setting information, control information, and the like are stored.

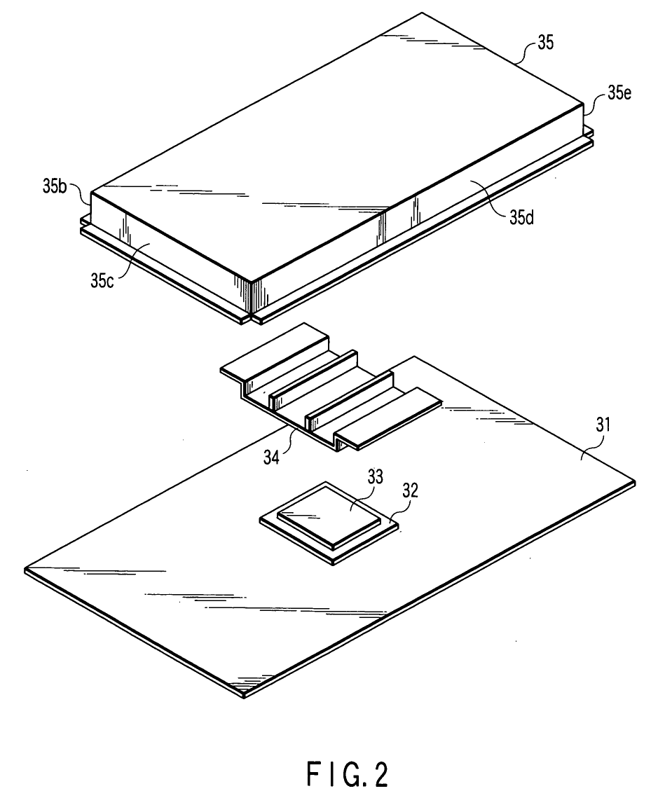

FIG. 2 shows a circuit board 31 on which the video signal processing system of the television broadcasting receiver 11 is arranged. That is, various types of circuit components, circuit patterns, and the like for constituting the video signal processing system are mounted on circuit board 31. A countermeasure for heat dissipation is required to, in particular, an LSI 32 constituting the decoder unit 15 in the various types of the circuit components mounted on the circuit board 31 because the LSI 32 generates heat when it processes digital data at high speed.

As the countermeasure for heat dissipation, a heat sink 34 is caused to come into intimate contact with the surface of the LSI 32 which is formed in an approximately square flat shape, located opposite to the surface thereof confronting the circuit board 31 through a flexible heat conduction sheet 33. Then, various types of circuit component are electromagnetically shielded by covering the surface of the circuit board 31, on which the LSI 32 is mounted, by a shied case 35 together with the heat sink 34.

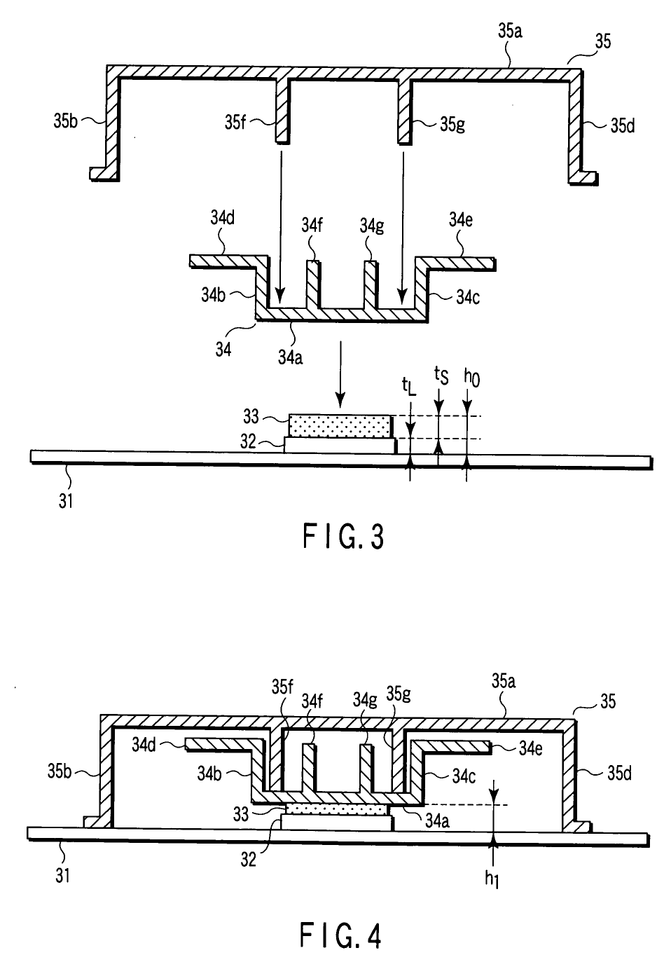

FIG. 3 shows structures of the heat sink 34 and the shield case 35. First, the heat sink 34 is composed of a base plate 34a formed in an approximately squire flat shape, a pair of side plates 34b and 34c extending from both confronting ends of the base plate 34a vertically in the same direction with respect to the surface of the base plate 34a, heat dissipation plates 34d and 34e extending externally from the apical ends of the side plates 34b and 34c in parallel to the base plate 34a, respectively, and a plurality of (two pieces in the illustrated example) heat dissipation plates 34f and 34g projecting from predetermined positions of the base plate 34a in parallel to the side plates 34b and 34c, and these members are formed integrally with each other by extrusion molding, for example, a metal material and the like having a heat *. Then, the heat sink 34 is attached such that the surface thereof opposite to the surface, on which the heat dissipation plates 34f and 34g of the base plate 34a is formed, comes into contact with the heat conduction sheet 33.

Further, the shield case 35 is composed of a flat plate 35a formed in an approximately square flat shape, four side plates 35b, 35c, 35d, and 35e extending from the four ends of the flat plate 35a in the same direction vertically with respect to the surface of the flat plate 35a, respectively, and a plurality (two pieces in the illustrated case) of presser portions 35f and 35g projecting from the flat plate 35a toward the base plate 34a of the heat sink 34, and these members are formed integrally with each other by press-molding, for example, a metal material and the like.

Note that the LSI 32 formed in the approximately square flat shape is mounted on one surface of the circuit board 31 such that one surface of the LSI 32 confronts the one surface of the circuit board 31. The heat conduction sheet 33 is attached to the other surface of the LSI 32, that is, to the surface opposite to the surface thereof confronting the circuit board 31.

The heat conduction sheet 33 is compressed by a load applied thereto from the outside. Accordingly, when the thickness of the heat conduction sheet 33 without load is shown by tS, and the thickness of the LSI 32 is shown by tL, the height h0 from the front surface of the circuit board 31 to the upper surface of the heat conduction sheet 33 when no load is applied thereto is shown by the following equation.
h0=tL+tS

As shown in FIG. 4, the shield case 35 covers the various types of the circuit components mounted on the circuit board 31 by being attached to the circuit board 31 such that the opening end thereof formed by the respective side plates 35b, 35c, 35d, and 35e come into contact with the surface of the circuit board 31.

The shield case 35 is arranged such that, when it is attached to the circuit board 31 as described above, the apical ends of the presser portions 35f and 35g of the shield case 35 press the base plate 34a of the heat sink 34 against the heat conduction sheet 33 by predetermined pressure. With this arrangement, a heat dissipation structure is completed by causing the base plate 34a of the heat sink 34 to come into intimate contact with the heat conduction sheet 33.

In this case, to prevent an excessive load from being applied to the LSI 32, the dimension of the presser portions 35f and 35g is set such that the height h1 from the front surface of the circuit board 31 to the upper surface of the heat conduction sheet 33 satisfies the following equation.
h1=tL+(1−k)·tS=h0−k·tS

where k shows the compression ratio of the heat conduction sheet 33 when load is applied thereto.

At the time, the value of k-tS is set larger than a mechanical dimensional tolerance. When, for example, the mechanical dimensional tolerance is set to ±0.3 mm as a design accuracy of a product, it is necessary to satisfy k·tS≧0.3.

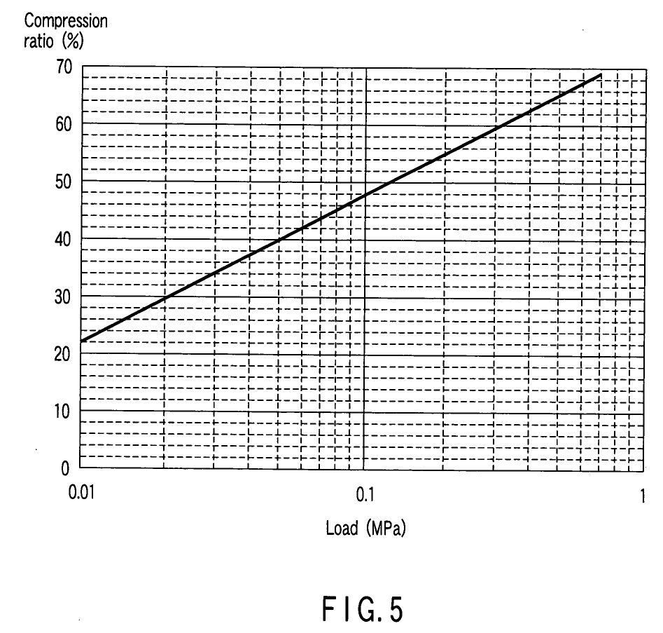

FIG. 5 shows an example of a relation between load and compression ratio of flexible silicon having a thickness tS of 1.5 mm without load as a material of the heat conduction sheet 33. Although it is preferable to suppress the compression ratio to reduce a load applied to the LSI 32, k set to about 30 to 60% is contemplated reasonable in view of the above described mechanical dimensional tolerance.

When it is assumed here that k is set to 40%, the value of k·tS is 40% of 1.5 mm, that is, 0.6 mm, which satisfies the condition of the mechanical dimensional tolerance of 0.3 or more. More specifically, when the heat sink is designed as in the example, the dimension of the presser portions 35f and 35g is set to h0−h1=0.6 mm.

Since it can be found from FIG. 5 that when k is set to 40%, the load is 0.05 MPa, from which the load applied to the LSI 32 is also 0.05 MPa. When the load has a value that does not undermine the reliability of the LSI 32 itself and the reliability to soldering to the circuit board 31 of the LSI 32, the heat sink 34 can be attached.

According to the embodiment described above, when the shield case 35 is attached to the circuit board 31, the heat sink 34 is caused to come into intimate contact with the heat conduction sheet 33 at appropriate pressure by the presser portions 35f and 35g of the shield case 35. Therefore, an arrangement for causing the heat sink 34 to come into pressure contact with the LSI 32 using a leaf spring, a coil spring, and the like is not necessary, thereby a heat dissipation effect can be sufficiently obtained by a simple arrangement.

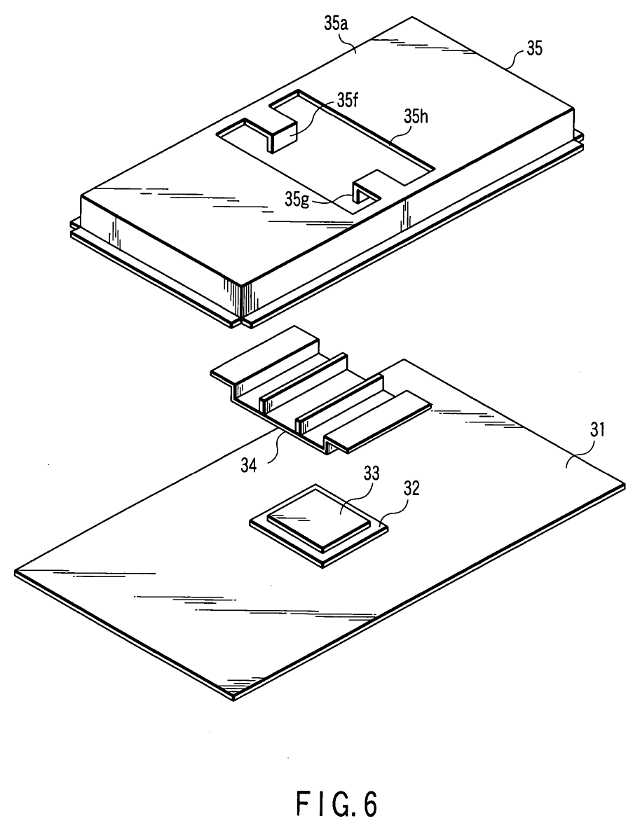

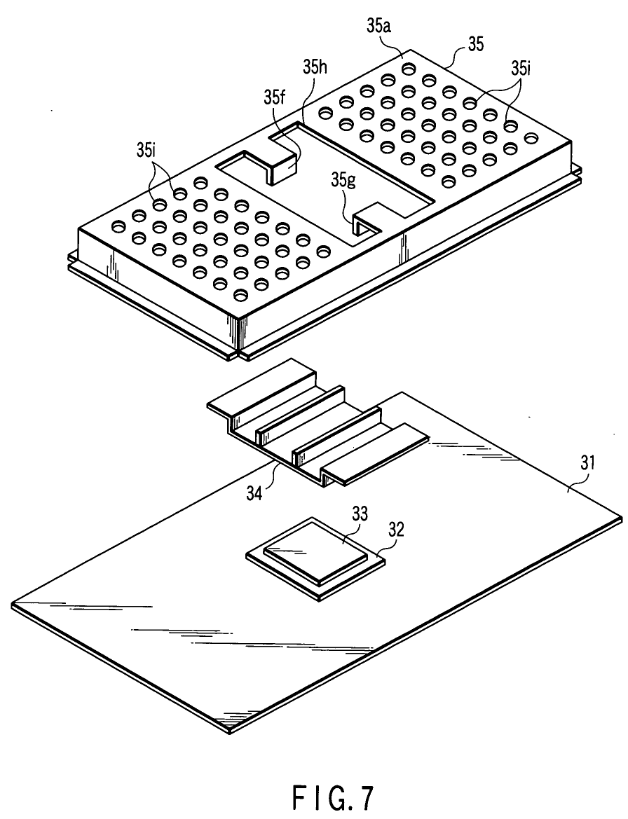

Further, as shown in FIG. 6, a cutout portion 35h may be formed to the portion of the flat plate 35a of the shield case 35 which corresponds to the attachment position of the heat sink 34 while remaining a part of the flat plate 35a, and the presser portions 35f and 35g may be formed by bending the remaining part of the flat plate 35a in an L-shape. With this arrangement, since the heat sink 34 is exposed to the outside through the cutout portion 35h, the heat dissipation effect can be enhanced.

Further, when a plurality of clearance holes 35i are formed to the flat plate 35a of the shield case 35 within a range by which a shield effect is not sacrificed, the heat dissipation effect can be more enhanced.

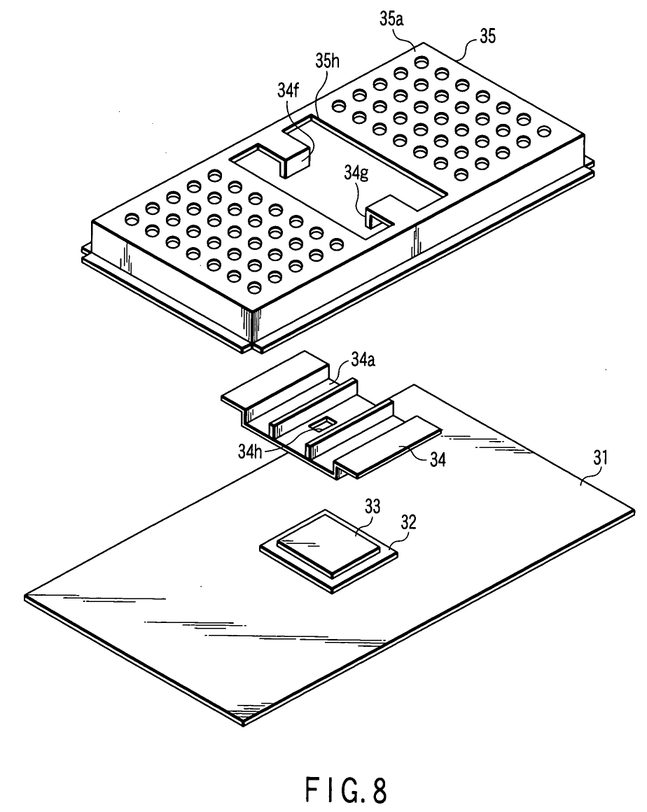

Further, when a clearance hole 34h is formed to the base plate 34a of the heat sink 34 as shown in FIG. 8, whether or not the heat sink 34 securely comes into intimate contact with the heat conduction sheet 33 can be visually determined by observing the bulging of the heat conduction sheet 33 in the clearance hole 34h through the cutout portion 35h when the shield case 35 is attached to the circuit board 31.

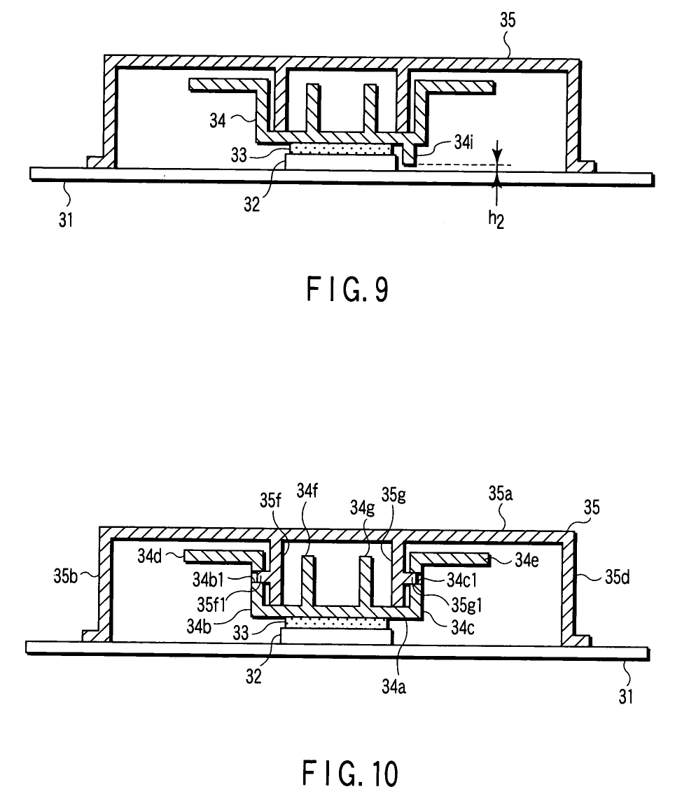

FIG. 9 shows another embodiment of the present invention. In FIG. 9, when explanation is made by denoting the same portions as those in FIG. 4 by the same reference numerals, a stopper 34i is formed at a predetermined position of a base plate 34a of a heat sink 34 so as to project toward a circuit board 31. When the dimension of presser portions 35f and 35g of a shield case 35 disperses beyond assumption, when external pressure is applied to a shield case 35, and the like, the stopper 34i comes into contact with the circuit board 31 and keeps a predetermined interval between the surface of the circuit board 31 and a heat sink 34 so that an unnecessary load is not applied to the LSI 32.

The interval h2 between the apical end of the stopper 34i and the circuit board 31 is set to satisfy the following equation.
h2=(kMAX−k)·tS

where kMAX shows a maximum allowable value of the dispersions of compression ratio k with respect to a heat conduction sheet 33. Since kMAX does not ordinarily exceed 1, h2 is set to satisfy the following equation.
h2<(1−k)·tS

FIG. 10 shows still another embodiment of the present invention. In FIG. 10, when explanation is made by denoting the same portions as those in FIG. 4 by the same reference numerals, locking holes 34b1 and 34c1 are formed to a pair of side plates 34b and 34c of a heat sink. Further, projections 35f1 and 35g1, which can be engaged with locking holes 34b1 and 34c1 formed to the side plates 34b and 34c, are formed to presser portions 35f and 35g of the shield case 35.

Accordingly, the heat sink 34 can be combined integrally with the shield case 35 by engaging projections 35f1 and 35g1 formed to the presser portions 35f and 35g of the shield case 35 with the locking holes 34b1 and 34c1 formed to the side plates 34b and 34c of the heat sink 34, thereby a workability in assembly can be enhanced.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A heat dissipation device for electronic equipment, comprising:
a circuit board on which a circuit component formed in an approximately flat plate shape is mounted;
a heat conduction sheet attached to the surface of the circuit component opposite to the surface thereof confronting the circuit board;
a heat sink in contact with the heat conduction sheet; and
a shield case which covers the surface of the circuit board including the circuit component and has presser portions formed thereto, the presser portions pressing, when the shield case covers the surface of the circuit board, the heat sink against the heat conduction sheet so that the heat sink comes into intimate contact with the heat conduction sheet at predetermined pressure.

2. A heat dissipation device for electronic equipment according to claim 1, wherein the shield case has a flat plate, which is formed approximately parallel to the surface of the circuit board when the shield case covers the surface of the circuit board, and the presser portions projecting from the flat plate at the positions thereof confronting the heat sink.

3. A heat dissipation device for electronic equipment according to claim 1, wherein the shield case has a flat plate, which is approximately parallel to the surface of the circuit board when the shield case covers the surface of the circuit board, and the presser portions are formed to the shield case by partly bending the flat plate.

4. A heat dissipation device for electronic equipment according to claim 1, wherein the shield case has a flat plate that is approximately parallel to the surface of the circuit board when the shield case covers the surface of the circuit board, and a cutout portion is formed to the flat plate to expose the heat sink pressed by the presser portions to the outside.

5. A heat dissipation device for electronic equipment according to claim 1, wherein a clearance hole is formed to the portion of the heat sink in contact with the heat conduction sheet so that the contact state of the heat sink with the heat conduction sheet can be observed therethrough.

6. A heat dissipation device for electronic equipment according to claim 1, wherein the dimension of the presser portions of the shield case is set such that when the shield case covers the surface of the circuit board, the interval h1 between the surface of the circuit board and the surface of the heat conduction sheet with which the heat sink comes into contact satisfies the following equation.
h1=tL+(1−k)·tS
where tS shows the thickness of the heat conduction sheet without load, tL shows the thickness tL of the circuit component, and k shows the compression ratio of the heat conduction sheet when load is applied thereto.

7. A heat dissipation device for electronic equipment according to claim 6, wherein the value of k-tS is set larger than a mechanical dimensional tolerance.

8. A heat dissipation device for electronic equipment according to claim 6, wherein the dimension of the presser portions of the shield case is set such that the compression ratio k of the heat conduction sheet is set within the range of 30 to 60%.

9. A heat dissipation device for electronic equipment according to claim 1, wherein the heat sink has a stopper for keeping a predetermined interval between the surface of the circuit board and the heat sink by coming into contact with the surface of the circuit board.

10. A heat dissipation device for electronic equipment according to claim 9, wherein the dimension of the stopper of the heat sink is set such that when the shield case covers the surface of the circuit board, the interval h2 between the surface of the circuit board and the stopper satisfies the following equation.
h2<(1−k)·tS
where tS shows the thickness of the heat conduction sheet without load, and k shows the compression ratio of the heat conduction sheet when load is applied thereto.

11. A heat dissipation device for electronic equipment according to claim 1, wherein the heat sink is supported by the shield case.

12. A heat dissipation device for electronic equipment, comprising:
a circuit board formed in a flat shape;
a flat-shaped circuit component mounted on one surface of the circuit board such that one surface of the circuit component of the flat-shaped circuit confronts the one surface of the circuit board;
a heat conduction sheet composed of a flexible material and attached to the surface of the circuit component opposite to the surface thereof confronting the circuit board;
a heat sink formed integrally of a base plate in contact with the heat conduction sheet, side plates extending from ends of the base plate vertically with respect to the surface of the base plate, and heat dissipation plates extending from ends of the side plates; and
a shield case which covers the surface of the circuit board including the heat sink formed integrally of a flat plate disposed approximately parallel to the surface of the circuit board, side plates extending from the peripheral edge portions of the flat plate, and presser portions projecting from predetermined positions of the flat plate in the same direction as the side plates and pressing the base plate of the heat sink against the heat conduction sheet.

13. A heat dissipation method for electronic equipment, comprising:
a first step of attaching a heat conduction sheet to the surface of an approximately flat-shaped circuit component mounted on a circuit board opposite to the surface thereof confronting the circuit board;
a second step of causing a heat sink to come into contact with the heat conduction sheet; and
a third step of causing the heat sink to come into intimate contact with the heat conduction sheet at predetermined pressure by presser portions formed to a shield case when the shield case covers the surface of the circuit board including the circuit component.
